(19) United States
(12) Patent Application Publication
(10) Pub. No.: US 2007/0261730 A1
(43) Pub. Date: Nov. 15, 2007

(54) Low dimensional thermoelectrics fabricated by semiconductor wafer etching

(75) Inventors: Fazila Seker, Clifton Park, NY (US); Fred Sharifi, Niskayuna, NY (US)

Correspondence Address: Paul DiConza,;GE Global Research, General Electric Company, Global IP & Legal Operation, Patent Agent, One Research Circle, K-1 3A60, Niskayuna, NY, 12309, US

(73) Assignee: General Electric Company, Schenectady, NY (US)

(21) Appl. No.: 11/433,087

(22) Filed: May 12, 2006

(51) Int. Cl. H01L 35/28

(52) U.S. Cl. 136/224

(57) ABSTRACT

In some embodiments, the present invention is directed to thermoelectric devices comprising nanostructured thermoelectric elements, such nanostructured thermoelements being formed by an etching of doped semiconductor wafers. The present invention is also directed to methods of making and using such thermoelectric devices, as well as to systems which employ such devices. Such devices and their manufacture are unique in that they employ a “top down” approach to the formation of the nanostructured or low-dimensional thermoelectric materials used therein.

### TECHNICAL FIELD

The present invention relates generally to heat transfer and power generation devices, and more particularly, to solid-state heat transfer devices.

### BACKGROUND INFORMATION

Heat transfer devices may be used for a variety of heating/cooling and power generation/heat recovery systems, such as refrigeration, air conditioning, electronics cooling, industrial temperature control, and power generation through waste heat recovery. These heat transfer devices are also scalable to meet the thermal management needs of a particular system and environment. However, existing heat transfer devices, such as those relying on refrigeration cycles, are environmentally unfriendly, have limited lifetime, and are bulky due to mechanical components such as compressors and the use of refrigerants.

In contrast, solid-state heat transfer devices offer certain advantages, such as, high reliability, reduced size and weight, reduced noise, low maintenance, and a more environmentally friendly device. For example, thermoelectric devices transfer heat by flow of charge through pairs of n-type and p-type semiconductor thermoelements, forming structures that are connected electrically in series (or parallel) and thermally in parallel. However, due to the relatively high cost and low efficiency of the existing thermoelectric devices, they are restricted to small scale applications, such as automotive seat coolers, generators in satellites and space probes, and for local heat management in electronic devices.

At a given operating temperature, the heat transfer efficiency of thermoelectric devices can be characterized by the figure-of-merit that depends on the Seebeck coefficient, electrical conductivity and the thermal conductivity of the thermoelectric materials employed for such devices. Many techniques have been used to increase the heat transfer efficiency of the thermoelectric devices through improving the figure-of-merit value, many of these focusing on low dimensional thermoelectric structures. For example, in some heat transfer devices two-dimensional superlattice thermoelectric materials have been employed for increasing the power factor value of such devices (see, e.g., Hicks et al., “Experimental study of the effect of quantum-well structures on the thermoelectric figure of merit,” Phys. Rev. B, vol. 53(16), R10493-R10496, 1996). Such devices may require deposition of two-dimensional superlattice thermoelectric materials through techniques, such as molecular beam epitaxy or vapor phase deposition. Other devices have employed one-dimensional nanorod systems (see U.S. patent application Ser. No. 11/138,615, filed 26 May 2005). All such devices, however, are fabricated using “bottom up” deposition methods. Accordingly, successful fabrication of such devices will require significant development of deposition techniques such that they afford sufficient control of doping, crystallinity, purity, and other relevant parameters for generating reliable high efficiency thermoelectric performance.

Accordingly, there remains a need to provide a thermal transfer device that has enhanced efficiency achieved through improved figure-of-merit of the thermal transfer device, and for methods of making such a device that are economical. It would also be advantageous to provide a device that is scalable to meet the thermal management needs of a particular system and environment.

### BRIEF DESCRIPTION OF THE INVENTION

In some embodiments, the present invention is directed to thermoelectric devices comprising nanostructured thermoelectric elements, such nanostructured thermoelements being formed by an etching of doped semiconductor wafers—many of which are commercially available. The present invention is also directed to methods of making and using such thermoelectric devices, as well as to systems which employ such devices. Such devices and their manufacture are unique in that they employ a “top down” approach to the formation of the nanostructured or low-dimensional thermoelectric materials used therein, thereby employing materials prepared by well-documented and established techniques providing device-ready thickness and device-quality purity.

In some such above-mentioned embodiments, the present invention is directed to a thermoelectric device comprising: (a) a first thermally conductive substrate having a first patterned electrode disposed thereon; (b) a second thermally conductive substrate having a second patterned electrode disposed thereon, wherein the first and second thermally conductive substrates are arranged such that the first and second patterned electrodes form an electrically continuous circuit; (c) a plurality of thermoelectric elements positioned between the first and second patterned electrodes, wherein the thermoelectric elements comprise nanostructures, and wherein the nanostructures are formed by electrochemically etching semiconducting material; and (d) a joining material disposed between the plurality of thermoelectric elements and at least one of the first and second patterned electrodes.

In some such above-mentioned embodiments, the present invention is directed to a method of manufacturing a thermoelectric device, the method comprising the steps of: (a) providing a first thermally conductive substrate having a first patterned electrode disposed thereon; (b) providing a second thermally conductive substrate having a second patterned electrode disposed thereon; (c) establishing a plurality of thermoelectric elements positioned between the first and second patterned electrodes, wherein the thermoelectric elements comprise nanostructures, and wherein the nanostructures are formed by electrochemically etching semiconducting; and (d) disposing a joining material between the plurality of thermoelectric elements and the first and second patterned electrodes.

The foregoing has outlined rather broadly the features of the present invention in order that the detailed description of the invention that follows may be better understood. Additional features and advantages of the invention will be described hereinafter which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a diagrammatical illustration of a system having a thermal transfer device, in accordance with some embodiments of the present invention;

FIG. 2 is a diagrammatical illustration of a power generation system having a thermal transfer device, in accordance with some embodiments of the present invention;

FIG. 3 is a cross-sectional view of a thermal transfer unit, in accordance with some embodiments of the present invention;

FIG. 4 depicts a process by which a doped semiconductor wafer is electrochemically etched to yield a nanostructured thermoelectric element, in accordance with some embodiments of the present invention;

FIG. 5 is a scanning electron microscopy (SEM) image depicting a nanostructured thermoelectric element comprising a dendritic morphology, in accordance with some embodiments of the present invention;

FIG. 6 is a SEM image depicting a nanostructured thermoelectric element comprising a triangular morphology, in accordance with some embodiments of the present invention;

FIG. 7 is a diagrammatical side view illustrating an assembled module of a thermal transfer device having a plurality of thermal transfer units, in accordance with some embodiments of the present invention; and

FIG. 8 is a perspective view illustrating a module having an array of thermal transfer devices, in accordance with some embodiments of the present invention.

### DETAILED DESCRIPTION OF THE INVENTION

In some embodiments, the present invention is directed to thermoelectric devices comprising nanostructured thermoelectric elements, such nanostructured thermoelements being formed by an etching of doped semiconductor wafers. The present invention is also directed to methods of making and using such thermoelectric devices, as well as to systems which employ such devices. Such devices and their manufacture are unique in that they employ a “top down” approach to the formation of the nanostructured or low-dimensional thermoelectric materials used therein.

The term “low-dimensional,” as used herein, generally refers to structures having features that are electronically two-dimensional or one-dimensional, as defined by establishment of (few) discrete energy bands in the small dimension(s). The term “nanostructured,” as it relates to the thermoelements of the present invention, incorporates features that are nanoscale in at least one dimension, e.g., nanorods or nanowires, or nanomesh. Typically, such structures are quantum confined, meaning that they possess features with sizes below which discrete energy states occur.

In the following description, specific details are set forth such as specific quantities, sizes, etc. so as to provide a thorough understanding of embodiments of the present invention. However, it will be obvious to those skilled in the art that the present invention may be practiced without such specific details. In many cases, details concerning such considerations and the like have been omitted inasmuch as such details are not necessary to obtain a complete understanding of the present invention and are within the skills of persons of ordinary skill in the relevant art.

Referring to the drawings in general, it will be understood that the illustrations are for the purpose of describing a particular embodiment of the invention and are not intended to limit the invention thereto.

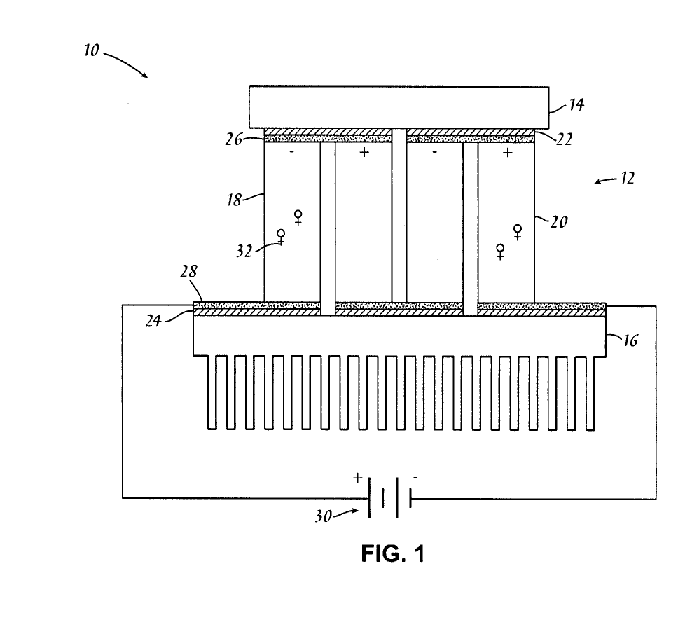

FIG. 1 illustrates a system 10 having a plurality of thermal transfer devices in accordance with certain embodiments of the present invention. As illustrated, the system 10 includes a thermal transfer module such as represented by reference numeral 12, comprised of thermoelectric elements 18 and 20, that transfers heat from an area or object 14 to another area or object 16 that may function as a heat sink for dissipating the transferred heat. Thermal transfer module 12 may be used for generating power or to provide heating or cooling of the components. Further, the components for generating heat such as object 14 may generate low-grade heat or high-grade heat. As will be discussed below, the first and second objects 14 and 16 may be components of a vehicle, or a turbine, or an aircraft engine, or a solid oxide fuel cell, or a refrigeration system. It should be noted that, as used herein the term “vehicle” may refer to a land-based, an air-based or a sea-based means of transportation. In this embodiment, the thermal transfer module 12 includes a plurality of thermoelectric devices. Note that generally such thermal transfer modules comprise at least a pair of such thermoelements; one being an n-type semiconductor leg, and the other being a p-type semiconductor leg.

In the above-described embodiment, the thermoelectric module 12 comprises n-type semiconductor legs 18 and p-type semiconductor legs 20 that function as thermoelements, whereby the temperature difference between object 14 and object 16 produces a voltage difference in the thermoelements in contact with these objects, allowing a current to flow, and generating electricity. In this embodiment, the n-type and p-type semiconductor legs (thermoelements) 18 and 20 are disposed on patterned electrodes 22 and 24 that are coupled to the first and second objects 14 and 16, respectively. In certain embodiments, the patterned electrodes 22 and 24 may be disposed on thermally conductive substrates (not shown) that may be coupled to the first and second objects 14 and 16. Further, interface layers 26 and 28 may be employed to electrically connect pairs of the n-type and p-type semiconductor legs 18 and 20 on the patterned electrodes 22 and 24.

In the embodiment described above and as depicted in FIG. 1, the n-type and p-type semiconductor legs 18 and 20 are coupled electrically in series and thermally in parallel. In certain embodiments, a plurality of pairs of n-type and p-type semiconductors 18 and 20 may be used to form thermocouples that are connected electrically in series and thermally in parallel for facilitating the heat transfer. In operation, an input voltage source 30 provides a flow of current through the n-type and p-type semiconductors 18 and 20. As a result, the positive and negative charge carriers transfer heat energy from the first electrode 22 onto the second electrode 24. Thus, the thermoelectric module 12 facilitates heat transfer away from the object 14 towards the object 16 by a flow of charge carriers 32 between the first and second electrodes 22 and

In certain embodiments, the polarity of the input voltage source 30 in the system 10 may be reversed to enable the charge carriers to flow from the object 16 to the object 14, thus cooling the object 16 and causing the object 14 to function as a heat sink. As described above, the thermoelectric module 12 may be employed for heating or cooling of objects 14 and 16. Further, the thermoelectric module 12 may be employed for heating or cooling of objects in a variety of applications such as air conditioning and refrigeration systems, cooling of various components in applications such as an aircraft engine, or a vehicle, or a turbine and so forth. In certain embodiments, the thermoelectric device 12 may be employed for power generation by maintaining a temperature gradient between the first and second objects 14 and 16, respectively that will be described below.

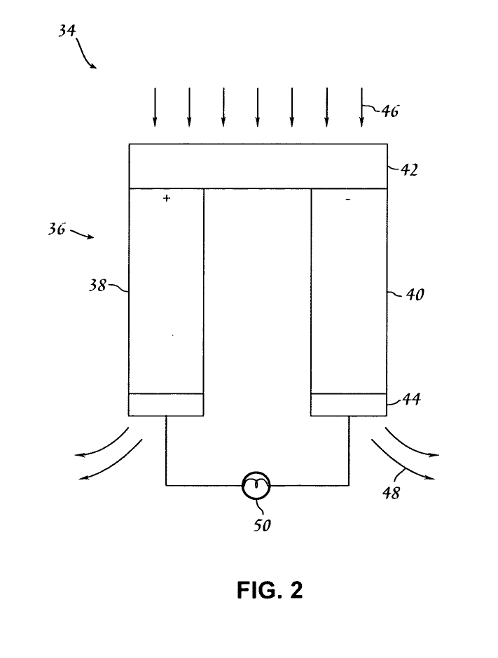

FIG. 2 illustrates a power generation system 34 having a thermal transfer device 36 in accordance with aspects of the present invention. The thermal transfer device 36 includes a p-type leg 38 and an n-type leg 40 configured to generate power by maintaining a temperature gradient between a first substrate 42 and a second substrate 44. In this embodiment, the p-type and n-type legs 38 and 40 are coupled electrically in series and thermally in parallel to one another. In operation, heat is pumped into the first interface 42, as represented by reference numeral 46 and is emitted from the second interface 44 as represented by reference numeral 48. As a result, an electrical voltage 50 proportional to a temperature gradient between the first substrate 42 and the second substrate 44 is generated due to a Seebeck effect that may be further utilized to power a variety of applications that will be described in detail below. Examples of such applications include, but are not limited to, use in a vehicle, a turbine and an aircraft engine. Additionally, such thermoelectric devices may be coupled to photovoltaic or solid oxide fuel cells that generate heat including low-grade heat and high-grade heat thereby boosting overall system efficiencies. It should be noted that a plurality of thermocouples having the p-type and n-type thermoelements 38 and 40 may be employed based upon a desired power generation capacity of the power generation system 34. Further, the plurality of thermocouples may be coupled electrically in series, for use in a certain application.

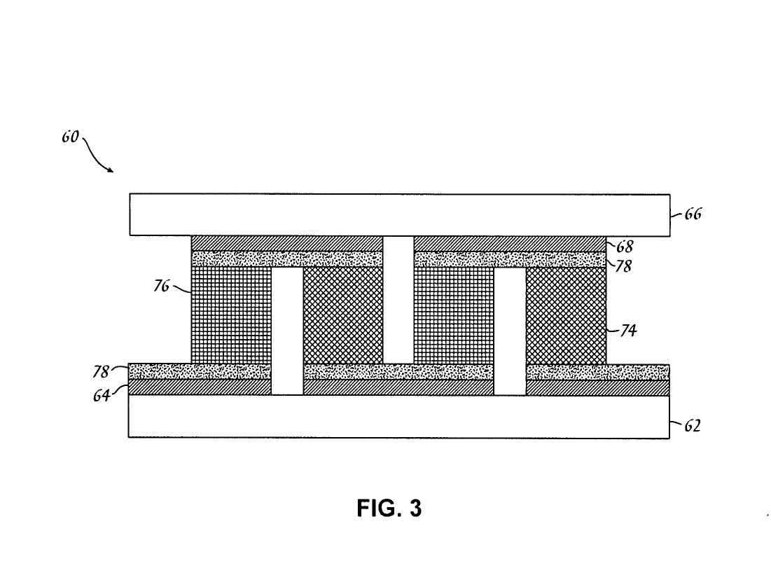

FIG. 3 illustrates a cross-sectional view of an exemplary configuration 60 of the thermal transfer device of FIGS. 1 and 2. The thermal transfer device or unit 60 includes a first thermally conductive substrate 62 having a first patterned electrode 64 disposed on the first thermally conductive substrate 62. The thermal transfer device 60 also includes a second thermally conductive substrate 66 having a second patterned electrode 68 disposed thereon. In this embodiment, the first and second thermally conductive substrates 62 and 66 comprise a thermally conductive and electrically insulating ceramic. For example, electrically insulating aluminum nitride or silicon carbide ceramic may be used for the first and second thermally conductive substrates 62 and 66. However, other thermally conductive and electrically insulating materials may be employed for the first and second thermally conductive substrates 62 and 66. In certain embodiments, the patterned electrodes 64 and 68 include a metal such as aluminum, copper and so forth. In certain embodiments, the patterned electrodes may include highly doped semiconductors. Further, the patterning of the electrodes 64 and 68 on the first and second thermally conductive substrates 62 and 66 may be achieved by utilizing techniques such as etching, photoresist patterning, shadow masking, lithography, or other standard semiconductor patterning techniques. In a presently contemplated configuration, the first and second thermally conductive substrates 62 and 66 are arranged such that the first and second patterned electrodes 64 and 68 are parallel and laterally offset to one another so as to form an electrically continuous circuit.

Moreover, a plurality of thermoelements (thermoelectric elements) 74 and 76 are established between the first and second patterned electrodes 64 and 68. Further, each of the plurality of thermoelements 74 and 76 is formed of a thermoelectric material, wherein the material is a doped semiconductor material, and where thermoelements 74 are p-doped and thermoelements 76 are n-doped (or vice versa). Examples of suitable thermoelectric materials include, but are not limited to, InP, InAs, InSb, silicon germanium based alloys, bismuth antimonide based alloys, lead telluride based alloys, bismuth telluride based alloys, or other III-V, IV, IV-VI, and II-VI semiconductors, or any combinations or alloy combinations thereof having substantially high thermoelectric figure-of-merit. Additionally suitable materials include ternary, quaternary, and higher order compound semiconductors.

The thermal transfer device 60 also includes a joining material 78 disposed between the plurality of thermoelements 74 and 76 and the first and second patterned electrodes 64 and 68 for reducing the electrical and thermal resistance of the interface. In certain embodiments, the joining material 78 between the thermoelements 74 and 76 and the first patterned electrode 64 may be different than the joining material 78 between the thermoelements 74 and 76 and the second patterned electrode 68. In one embodiment, the joining material 78 includes silver epoxy. It should be noted that other conductive adhesives may be employed as the joining material 78. In particular, the joining material 78 is disposed between the substrate 72 and the patterned electrode 64.

In some other embodiments, the thermoelements 74 and 76 may be bonded to the patterned electrodes 64 and 68 by diffusion bonding through atomic diffusion of materials at the joining interface or other techniques such as wafer fusion bonding for semiconductor interfaces. As will be appreciated by one skilled in the art, diffusion bonding causes micro-deformation of surface features leading to sufficient contact on an atomic scale to cause the two materials to bond. In certain embodiments, gold may be employed as an interlayer for the bonding and the diffusion bonds may be achieved at relatively low temperatures of about 300° C. In certain other embodiments indium or indium alloys may be employed as an interlayer for the bonding at temperatures of about 100° C. to about 150° C. Further, a typical solvent cleaning step may be applied on the surfaces to achieve flat and clean surfaces for applying diffusion bonding. Examples of solvents for the cleaning step include acetone, isopropanol, methanol and so forth. Further, metal coatings may be disposed on the top and bottom surfaces of the thermoelements 74 and 76 and the substrate 72 to facilitate the bonding between the thermoelements and the first and second substrates 62 and 66. In one embodiment, the thermoelements 74 and 76 may be bonded to the patterned electrodes 64 and 68 through direct diffusion bonding. Alternatively, the thermoelements 74 and 76 may be bonded to the patterned electrodes 64 and 68 via an interlayer, such as gold, metal, or solder metal alloy foil. In certain embodiments, the bonding between the thermoelements 74 and 76 and the first and second substrates 62 and 66 may be achieved through an interface layer such as silver epoxy. However, other joining methods may be employed to achieve the bonding between the thermoelements 74 and 76 and the first and second substrates 62 and 66.

In a presently contemplated configuration, the thermoelements 74 and 76 comprise nanostructured morphologies where quantum confinement effects are dominant. Typically, this involves nanostructures with dimensions below about 30 nm, and such nanostructures are generally formed using an electrochemical etching process. Further, the electronic density of states of the charge carriers and phonon transmission characteristics can be controlled by altering the morphology and composition of the thermoelements 74 and 76, thereby enhancing the efficiency of the thermoelectric devices that is characterized by the figure-of-merit of the thermoelectric device. As used herein, “figure-of-merit” (ZT) refers to a measure of the performance of a thermoelectric device and is represented by the equation:
ZT=α²T/ρK_{T} (1)
where: α is the Seebeck coefficient;
   T is the absolute temperature;
   ρ is the electrical resistivity of the thermoelectric material; and
   K_{T} is thermal conductivity of the thermoelectric material.

In some embodiments, the thermal transfer device of FIGS. 1-3 may include multiple layers, each of the layers having a plurality of thermoelements to provide appropriate materials composition and doping concentrations to match the temperature gradient between the hot and cold sides for achieving maximum figure-of-merit (ZT) and efficiency.

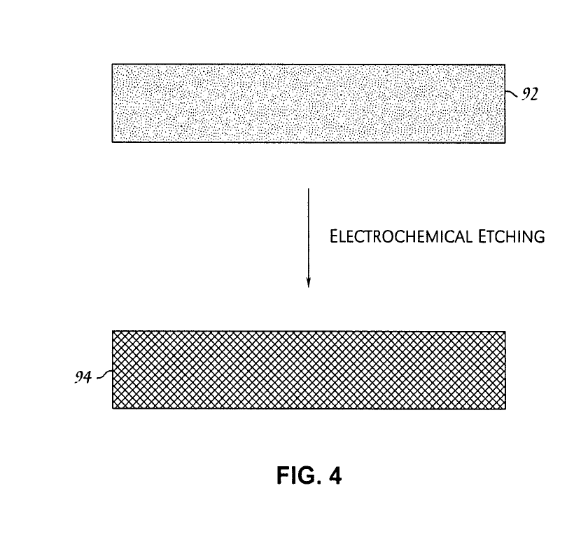

In contrast to previous methods for making nanostructured thermoelectric devices using a “bottom up” approach to the formation of the nanostructures (see U.S. patent application Ser. No. 11/138,615, filed 26 May 2005), the present invention employs a top down approach. Referring to FIG. 4, in some embodiments, an n- or p-doped semiconductor wafer 92 (precursor to thermoelements 74 and 76) is electrochemically etched to yield a nanostructured material 94 comprising nano- or low-dimensional structures which make the material suitable for use as a thermoelement in a thermoelectric device. As mentioned above, such nanostructures exhibiting enhanced thermoelectric performance relative to the corresponding bulk parent material typically comprise features with dimensions below about 30 nm.

In fabricating such above-mentioned thermoelements, in some embodiments a doped wafer of thickness on the order of hundreds of micrometers is chosen, wherein the doping densities are chosen for particular thermoelectric performance (typically, such doping densities are ca. 10¹⁷-10²⁰ cm⁻³). The wafer is then etched via anodization (ca. a few Volts (V)). Depending on the wafer material and on the anodization conditions, the wafer becomes nanostructured upon etching. The nanostructures can be one of a variety of morphologies including, but not limited to, dendritic morphology, triangular morphology, vertical cylindrical pores, nanomesh, and combinations thereof.

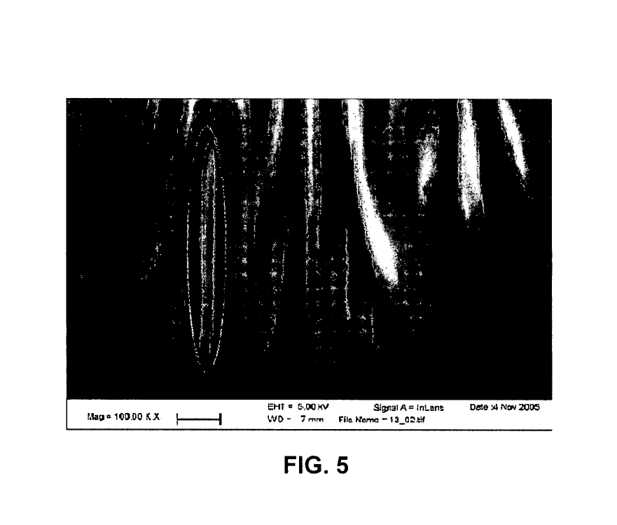

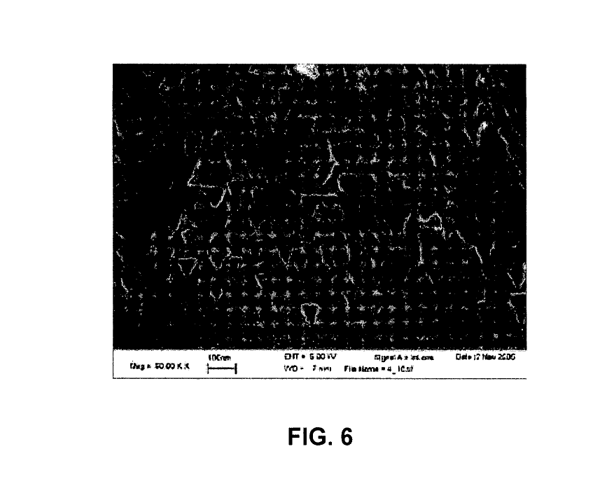

As an example of the above-described thermoelement fabrication, for a (100)-oriented n-InP wafer (resistivity of 1.07×10⁻³ ohm-cm; 380-420 μm thick wafer), using a sputter-coated TiW/Au as back contact, a triangular morphology was obtained for anodization potentials less than 1.6 V vs SCE (saturated calomel electrode as reference), and the dendritic morphology was observed for potentials greater than 1.6 V vs SCE. All such exemplary anodizations were conducted in a 1 M HCl solution, with or without added nitric acid (3 mL nitric acid in 200 mL 1 M HCl solution), and in a manner similar to that described in Fujikura et al., “Electrochemical Formation of Uniform and Straight Nano-Pore Arrays on (001) InP Surfaces and Their Photoluminescence Characteristics,” Jpn. J. Appl. Phys., Vol 39, pp. 4616-4620, 2000. It should be stressed that both morphologies can potentially exhibit enhanced thermoelectric performance provided that the size of the nanoscale features are below that which discrete energy states occur. FIG. 5 is a scanning electron microscopy (SEM) image depicting a InP nanostructured thermoelectric element comprising a dendritic morphology, while FIG. 6 depicts the same having a triangular morphology. For additional details on anodic etching of InP see Langa et al., “Formation of Porous Layers with Different Morphologies During Anodic Etching of n-InP,” Electrochemical and Solid-State Lett., 3(11), 514-516 (2000).

The nanostructured thermoelectric elements are incorporated as depicted in FIG. 3. Specifically, the nanostructured thermoelements are bonded to the patterned electrodes using a suitable joining material and process (see above).

Variations on the above-described method embodiments include: (a) a second preparative step involving wet etching of the anodized wafer to create nanowires or other nanostructures; (b) a surface passivation step to reduce electronic defect states; and (c) filling the void space of the nanostructured wafer 94 with insulating material (e.g., polymer) for added mechanical support.

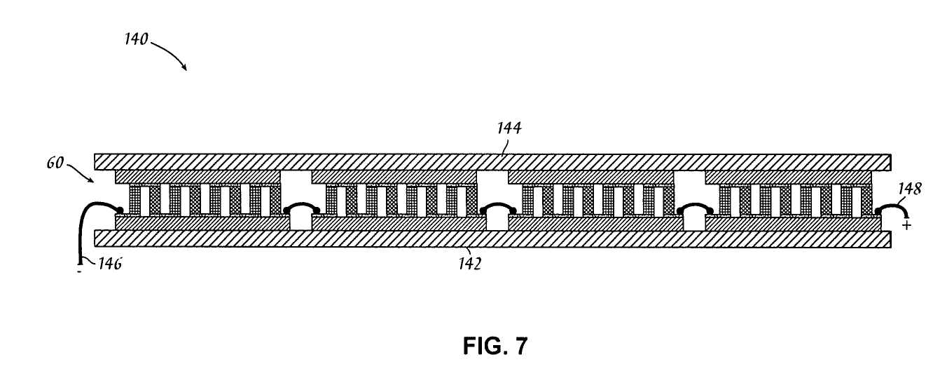

FIG. 7 illustrates a cross-sectional side view of a thermal transfer device or an assembled module 140 having a plurality of thermal transfer devices or thermal transfer units 60 in accordance with embodiments of the present technique. In the illustrated embodiment, the thermal transfer units 60 are mounted between opposite substrates 142 and 144 and are electrically coupled to create the assembled module 140. In this manner, the thermal transfer devices 60 cooperatively provide a desired heating or cooling capacity, which can be used to transfer heat from one object or area to another, or provide a power generation capacity by absorbing heat from one surface at higher temperatures and emitting the absorbed heat to a heat sink at lower temperatures. In certain embodiments, the plurality of thermal transfer units 60 may be coupled via a conductive joining material, such as silver filled epoxy or a metal alloy. The conductive joining material or the metal alloy for coupling the plurality of thermal transfer devices 60 may be selected based upon a desired processing technique and a desired operating temperature of the thermal transfer device. Finally, the assembled module 60 is coupled to an input voltage source via leads 146 and 148. In operation, the input voltage source provides a flow of current through the thermal transfer units 60, thereby creating a flow of charges via the thermoelectric mechanism between the substrates 142 and 144. As a result of this flow of charges, the thermal transfer devices 60 facilitate heat transfer between the substrates 142 and 144. Similarly, the thermal transfer devices 60 may be employed for power generation and/or heat recovery in different applications by maintaining a thermal gradient between the two substrates 142 and 144

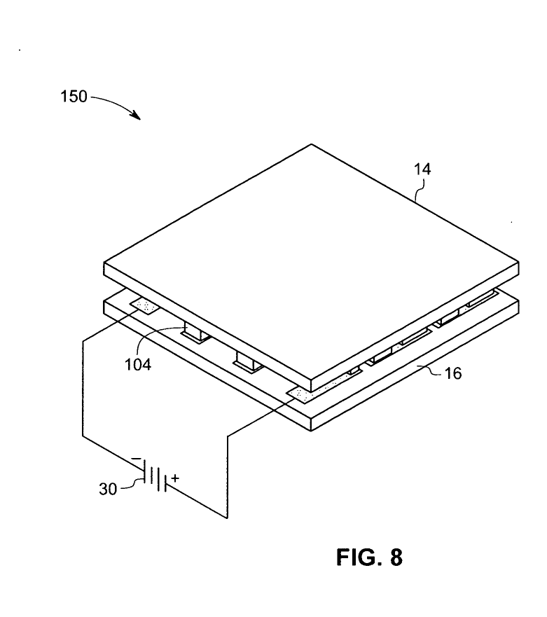

FIG. 8 illustrates a perspective view of a thermal transfer module 150 having an array of thermal transfer thermoelements 104 in accordance with embodiments of the present technique. In this embodiment, the thermal transfer devices 104 are employed in a two-dimensional array to meet a thermal management need of an environment or application. The thermal transfer devices 104 may be assembled into the heat transfer module 150, where the devices 104 are coupled electrically in series and thermally in parallel to enable the flow of charges from the first object 14 in the module 150 to the second object 16 thereby facilitating heat transfer between the first and second objects 14 and 16 in the module 150. It should be noted that the voltage source 30 may be a voltage differential that is applied to achieve heating or cooling of the first or second objects 14 and 16. Alternatively, the voltage source 30 may represent an electrical voltage generated by the module 150 when used in a power generation application.

Various aspects of the techniques described above find utility in a variety of heating/cooling systems, such as refrigeration, air conditioning, electronics cooling, industrial temperature control, and so forth. The thermal transfer devices as described above may be employed in air conditioners, water coolers, climate controlled seats, and refrigeration systems including both household and industrial refrigeration. For example, such thermal transfer devices may be employed for cryogenic refrigeration, such as for liquefied natural gas (LNG) or superconducting devices. Further, the thermal transfer devices as described above may be employed for cooling of components in various systems, such as, but not limited to vehicles, turbines and aircraft engines. For example, a thermal transfer device may be coupled to a component of an aircraft engine such as, a fan, or a compressor, or a combustor or a turbine case. An electric current may be passed through the thermal transfer device to create a temperature differential to provide cooling of such components.

Alternatively, the thermal transfer device described herein may utilize a naturally occurring or manufactured heat source to generate power. For example, the thermal transfer devices described herein may be used in conjunction with geothermal based heat sources where the temperature differential between the heat source and the ambient (whether it be water, air, etc.) facilitates power generation. Similarly, in an aircraft engine the temperature difference between the engine core air flow stream and the outside air flow stream results in a temperature differential through the engine casing that may be used to generate power. Such power may be used to operate or supplement operation of sensors, actuators, or any other power applications for an aircraft engine or aircraft. Additional examples of applications within which thermoelectric devices described herein may be used include gas turbines, steam turbines, vehicles, and so forth. Such thermoelectric devices may be coupled to photovoltaic or solid oxide fuel cells that generate heat thereby boosting overall system efficiencies.

The thermal transfer devices described above may also be employed for thermal energy conversion and for thermal management. It should be noted that the materials and the manufacturing techniques for the thermal transfer device may be selected based upon a desired thermal management need of an object. Such devices may be used for cooling of microelectronic systems such as microprocessor and integrated circuits. Further, the thermal transfer devices may be employed for thermal management of semiconductor devices, photonic devices, and infrared sensors.

A prime advantage of the present invention over existing methods is that, at least for some embodiments, the present invention permits the use of semiconductor wafers of known electrical, structural and thermal properties, available from wafer suppliers, as the starting material for the fabrication, via electrochemical etching, of the low dimensional thermoelectric structures described herein. Methods of the present invention permit the rapid, inexpensive, and reproducible fabrication of low dimensional thermoelectrics that can be easily integrated into practical devices.

The following examples are included to demonstrate particular embodiments of the present invention. It should be appreciated by those of skill in the art that the methods disclosed in the examples that follows merely represent exemplary embodiments of the present invention. However, those of skill in the art should, in light of the present disclosure, appreciate that many changes can be made in the specific embodiments described and still obtain a like or similar result without departing from the spirit and scope of the present invention.

### EXAMPLE 1

This Example serves to illustrate etching of a semiconductor wafer to form low-dimensional or nanostructured thermoelectric elements for use in thermoelectric devices, in accordance with some embodiments of the present invention.

An InP wafer ((100) orientation, 500 μm thick, 10¹⁷-10¹⁸ cm⁻³ doping, n-type) is electrically contacted to a Pt back contact. The InP electrode prepared in this way is immersed into an aqueous 1 M HCl electrolyte solution. A 4 mm² window of the InP electrode is exposed for anodization in the dark at room temperature using a 3-electrode configuration at anode potentials of 1 to 2 V with respect to a reference electrode. Depending on the voltage and solution conditions used, anodization times providing the appropriate etching depths are used, thereby providing a high level of control over the formation of the nanostructures.

### EXAMPLE 2

This Example serves to illustrate the incorporation of an etched semiconductor wafer into a thermoelectric device, in accordance with some embodiments of the present invention.

In constructing a device incorporating the etched wafer of EXAMPLE 1, the following steps can be taken: (1) The wafer can be etched to >50% of the total wafer thickness, thereby developing the desired morphology over a significant fraction of the wafer; (2) In a subsequent step, the void space of the etched structure may optionally be filled with insulating material (e.g., polymer) for added mechanical support using established techniques (i.e., spin casting the filler from solution, vapor deposition processes); (3) The device is then assembled by bonding equal numbers of both p- and n-type etched wafers to the metal electrodes of the patterned thermally-conductive substrate 62 and 66 in device 60 described above using known bonding techniques, as described herein. The p- and n-type etched wafers comprise thermoelements of the device, and are arranged in alternating fashion, as shown in FIGS. 1 and 3.

It will be understood that certain of the above-described structures, functions, and operations of the above-described embodiments are not necessary to practice the present invention and are included in the description simply for completeness of an exemplary embodiment or embodiments. In addition, it will be understood that specific structures, functions, and operations set forth in the above-described referenced patents and publications can be practiced in conjunction with the present invention, but they are not essential to its practice. It is therefore to be understood that the invention may be practiced otherwise than as specifically described without actually departing from the spirit and scope of the present invention as defined by the appended claims.

What is claimed is:

1. A thermoelectric device comprising:
a) a first thermally conductive substrate having a first patterned electrode disposed thereon;
b) a second thermally conductive substrate having a second patterned electrode disposed thereon, wherein the first and second thermally conductive substrates are arranged such that the first and second patterned electrodes are connected to form a continuous electrical circuit;
c) a plurality of thermoelectric elements positioned between the first and second patterned electrodes, wherein the thermoelectric elements comprise a plurality of nanostructures, and wherein the nanostructures are formed by electrochemically etching doped semiconducting material; and
d) a joining material disposed between the plurality of thermoelectric elements and at least one of the first and second patterned electrodes.

2. The thermoelectric device of claim 1, wherein the first and second thermally conductive substrates comprise an electrically insulating aluminum nitride ceramic or an electrically insulating silicon carbide material.

3. The thermoelectric device of claim 1, wherein the semiconducting material of which the nanostructures are formed is a thermoelectric material largely selected from the group consisting of silicon germanium based alloys; bismuth antimony based alloys; lead telluride based alloys; bismuth telluride based alloys; III-V, IV, V, IV-VI, and II-VI semiconductors; and ternary and quaternary alloy combinations thereof.

4. The thermoelectric device of claim 1, wherein the semiconducting material of which the nanostructures are formed is a group III-V semiconductor selected from the group consisting of InP, InAs, InSb, and combinations thereof.

5. The thermoelectric device of claim 1, wherein the plurality of nanostructures comprise a morphology selected from the group consisting of dendritic morphologies, triangular morphologies, vertical cylindrical pores, nanomesh, and combinations thereof.

6. The thermoelectric device of claim 1, wherein each of the plurality of thermoelectric elements comprises either p-type material or n-type material.

7. The thermoelectric device of claim 1, wherein the plurality of thermoelectric elements are organized into a plurality of thermal transfer units, wherein the plurality of thermal transfer units are electrically coupled between opposite substrates.

8. The thermoelectric device of claim 1, wherein the device is configured to generate power by substantially maintaining a temperature gradient between the first and second thermally conductive substrates.

9. The thermoelectric device of claim 1, wherein introduction of current flow between the first and second thermally conductive substrates enables heat transfer between the first and second thermally conductive substrates via a flow of charge between the first and second thermally conductive substrates.

10. The thermoelectric device of claim 1, wherein the thermoelectric elements are connected electrically in series and thermally in parallel.

11. The thermoelectric device of claim 1, wherein the device is an integral part of a system selected from the group consisting of a vehicle, a power source, a heating system, a cooling system, and combinations thereof.

12. A method of manufacturing a thermoelectric device, the method comprising the steps of:
a) providing a first thermally conductive substrate having a first patterned electrode disposed thereon;
b) providing a second thermally conductive substrate having a second patterned electrode disposed thereon;
c) establishing a plurality of thermoelectric elements positioned between the first and second patterned electrodes, wherein the thermoelectric elements comprise a plurality of nanostructures, and wherein the nanostructures are formed by electrochemically etching doped semiconducting material; and
d) disposing a joining material between the plurality of thermoelectric elements and the first and second patterned electrodes.

13. The method of claim 12, wherein the first and second thermally conductive substrates comprise an electrically insulating aluminum nitride ceramic, or an electrically insulating silicon carbide material.

14. The method of claim 12, wherein the semiconducting material of which the nanostructures are formed is a thermoelectric material largely selected from the group consisting of silicon germanium based alloys; bismuth antimony based alloys; lead telluride based alloys; bismuth telluride based alloys; III-V, IV, V, IV-VI, and II-VI semiconductors; and ternary and quaternary alloy combinations thereof.

15. The method of claim 12, wherein the semiconducting material of which the nanostructures are formed is a group III-V semiconductor selected from the group consisting of InP, InAs, InSb, and combinations thereof.

16. The method of claim 12, wherein the nanostructures comprise a morphology selected from the group consisting of dendritic morphologies, triangular morphologies, vertical cylindrical pores, nanomesh, and combinations thereof.

17. The method of claim 12, wherein each of the plurality of thermoelectric elements comprises either p-type material or n-type material.

18. A system comprising:
a) a heat source;
b) a heat sink; and
c) a thermoelectric device coupled between the heat source and the heat sink and configured to provide cooling or to generate power, the device comprising;
i) a first thermally conductive substrate having a first patterned electrode disposed thereon;
ii) a second thermally conductive substrate having a second patterned electrode disposed thereon, wherein the first and second thermally conductive substrates are arranged such that the first and second patterned electrodes are connected so as to form an electrically continuous circuit;
iii) a plurality of thermoelectric elements positioned between the first and second patterned electrodes, wherein the thermoelectric elements comprise a plurality of nanostructures, and wherein the nanostructures are formed by electrochemically etching doped semiconducting material; and
iv) a joining material disposed between the plurality of thermoelectric elements and at least one of the first and second patterned electrodes.

19. The system of claim 18, wherein the first and second thermally conductive substrates comprise an electrically insulating aluminum nitride ceramic, or an electrically insulating silicon carbide material.

20. The system of claim 18, wherein the semiconducting material of which the nanostructures are formed is a thermoelectric material largely selected from the group consisting of silicon germanium based alloys; bismuth antimony based alloys; lead telluride based alloys; bismuth telluride based alloys; III-V, IV, V, IV-VI, and II-VI semiconductors; and ternary and quaternary combinations thereof.

21. The system of claim 18, wherein the plurality of nanostructures comprise a morphology selected from the group consisting of dendritic morphologies, triangular morphologies, vertical cylindrical pores, nanomesh, and combinations thereof.

22. The system of claim 18, wherein each of the plurality of thermoelectric elements comprises either p-type material or n-type material.
